(19) United States
(12) Patent Application Publication
(10) Pub. No.: US 2026/0211059 A1
(43) Pub. Date: Jul. 23, 2026

(54) SYSTEM AND METHOD FOR DETECTING A FAULTY CONNECTION TO EARTH IN AN EARTH GRID FROM AN EQUIPMENT

(71) Applicant: JEF TECHNO SOLUTIONS PVT LTD, Bangalore (IN)

(72) Inventor: Prashanth Belur Gururaja Rao, Bangalore (IN)

(21) Appl. No.: 19/143,800

(22) PCT Filed: Dec. 26, 2023
(86) PCT No.: PCT/IN2023/051225

§ 371 Date: Jun. 26, 2025

(30) Foreign Application Priority Data
Dec. 27, 2022 (IN) 202243075912

(51) Int. Cl. G01R 31/52

(52) U.S. Cl. CPC G01R 31/52

(57) ABSTRACT

A system for detecting a faulty connection to earth in an earth grid (104) from an equipment is provided. The system includes an earth grid, a plurality of equipment (102A-B), a current injection device (110), a plurality of current measuring devices (116, 118), a plurality of the first risers (106A-B)and a second riser (108). A first reference riser and the second riser receive the input current from the current injection device and provide input current to earth grid for detecting a defective riser or a faulty connection. The first current measuring device measures a first current that is received by the second riser from earth grid and the second current measuring device measures a second current that is received by the second riser from the second equipment. The system determines faulty connection to earth in the earth grid from the equipment by comparing the first current, the second current, and the input current.

### BACKGROUND

### Technical Field

The embodiments herein generally relate to detection of a faulty connection to earth in an earth grid from an equipment, and more particularly, to a system and method for detecting the faulty connection to earth in the earth grid from the equipment using a current injection device and a current measuring device.

### Description of the Related Art

In an electrical system, a grid connection from electric substations is permanently buried under the ground and it is not easily accessible. Accident typically happens when people come in contact with an equipment connected to the buried earth grid where such connections have breakage/damage. The breakage in the earth grid buried under the ground may cause major accident during the damage in the earth grid.

The existing system gauges a damage in the earth grid (i.e. riser) by measuring an effective resistance between the earth grid and the equipment. The drawback of the existing system is that it is not possible to identify which riser is defective and the riser is defective at the equipment or at the earth grid. Further, it is very important to detect a faulty connection in the system which has only one riser in between the equipment and the earth grid as there are no other riser which are connected to the equipment and the earth grid. If there is a damage/breakage in the single riser system, the chances of accidents and causalities are very high.

As mentioned, there remains a need for a system or a method to detect a faulty connection to earthen the earth grid from the equipment.

### SUMMARY

In view of the foregoing, an embodiment herein provides a system for detecting a faulty connection to earth in an earth grid from an equipment. The system comprises an earth grid, a plurality of equipment that is connected to the earth grid and a current injection device. The plurality of equipment comprises a first equipment that is connected to the earth grid through a plurality of first risers, and a second equipment that is connected to the earth grid through a second riser. The current injection device comprises a frequency converter that modifies an input current with grid frequency into an input current with off grid frequency, and a current unit that regulates the input current with off grid frequency into a variable input current with off grid frequency. When the current injection device is electrically connected to (i) a first reference riser from the plurality of the first risers at a first current injection point and (ii) the second riser at a second current injection point, the first reference riser and the second riser receive the input current with off-grid frequency from the current injection device and provide the input current with off-grid frequency to the earth grid for detecting a defective riser or a faulty connection to the earth grid. When the current injection device is electrically connected to (i) the first reference riser from the plurality of the first risers at the first current injection point and (ii) a pole structure of the second equipment at a third current injection point, the first reference riser and the pole structure receive the input current with off-grid frequency from the current injection device for detecting a faulty connection in a first termination point where the second riser is terminated on the pole structure. The system comprises a plurality of current measuring devices comprising a first current measuring device and a second current measuring device. When the first current measuring device is connected to the second riser below the second current injection point and the second current measuring device is connected to the second riser above the second current injection point, the first current measuring device measures a first current that is received by the second riser from the earth grid and the second current measuring device measures a second current that is received by the second riser from the second equipment. When the first current measuring device is connected to the second riser below the first termination point and the second current measuring device is connected to the pole structure of the second equipment above the first termination point, the first current measuring device measures the first current that is received by the second riser from the earth grid and the second current measuring device measures a third current that is received from the pole structure of the second equipment.

The system compares the first current, the second current, the third current, and the input current and determines a faulty connection in (i) the first termination point, if at least one of (a) the third current that is received by the pole structure of the second equipment is below the first current that is received by the second riser from the earth grid, (b) the third current that is received by the pole structure of the second equipment, is below the input current, or (c) the third current that is received by the pole structure of the second equipment is zero, and (ii) the earth grid, if at least one of (a) the first current that is received by the second riser from the earth grid is below the second current that is received by the second riser from the second equipment, (b) the first current that is received by the second riser from the earth grid is below the input current, or (c) the first current that is received by the second riser from the earth grid is zero.

In some embodiments, when the current injection device is electrically connected to (i) the first reference riser from the plurality of the first risers at the first current injection point and (ii) a frame of the second equipment at a fourth current injection point, the first reference riser and the frame of the second equipment receive the input current with off-grid frequency from the current injection device for detecting a faulty connection in a second termination point where the pole structure of the second equipment is bonded with the frame. When the first current measuring device is connected to the pole structure of the second equipment below the second termination point and the second current measuring device is connected to the frame of the second equipment above the second termination point, the first current measuring device measures the first current that is received by the pole structure of the second equipment from the earth grid and the second current measuring device measures a fourth current that is received by the frame of the second equipment. The system compares the first current, the fourth current, and the input current and determines a faulty connection in the second termination point, if at least one of (a) the fourth current that is received by the frame of the second equipment is below the first current that is received by the pole structure of the second equipment from the earth grid, (b) the fourth current that is received by the frame of the second equipment, is below the input current, or (c) the fourth current that is received by the pole structure of the second equipment is zero.

In some embodiments, when the current injection device is electrically connected to (i) the first reference riser from the plurality of the first risers at the first current injection point and (ii) the second equipment at a fifth current injection point, the first reference riser and the second equipment receive the input current with off-grid frequency from the current injection device for detecting a faulty connection in a third termination point where the frame of the second equipment is bonded with the second equipment. When the first current measuring device is connected to the frame of the second equipment below the third termination point and the second current measuring device is connected to the second equipment above the third termination point, the first current measuring device measures the first current that is received by the frame of the second equipment from the earth grid and the second current measuring device measures a fifth current that is received by the second equipment. The system compares the first current, the fifth current, and the input current and determines a faulty connection in the third termination point, if at least one of (a) the fifth current that is received by the second equipment is below the first current that is received by the frame of the second equipment from the earth grid, (b) the fifth current that is received by the second equipment, is below the input current, or (c) the fifth current that is received by the second equipment is zero.

In some embodiments, the input current ranges from 1 ampere to 20 amperes. In some embodiments, the input current ranges from 1 ampere to 40 amperes. In some embodiments, the input current comprise an alternate current (AC) or a direct current (DC). In some embodiments, the first reference riser is a conductor that connects the current injection device and the earth grid.

In some embodiments, the first reference riser is a node taken from the earth grid to provide the input current from the current injection device to the earth grid, wherein the second riser is a node taken from the second equipment or a body of the second equipment to provide the input current from the current injection device to the second equipment or a body of the second equipment.

In some embodiments, the second riser under test is a conductor that is connected with (i) the second equipment or a body of the second equipment and (ii) the earth grid.

In an aspect, an embodiment herein provides a method for detecting a faulty connection to earth in an earth grid from an equipment, wherein the earth grid is connected to a plurality of equipment, wherein a first equipment from the plurality of equipment is connected to the earth grid through a plurality of first risers and a second equipment from the plurality of equipment is connected to the earth grid through a second riser. The method comprises: (A) modifying, using a frequency converter of a current injection device of a system, an input current with grid frequency into an input current with off grid frequency; (B) regulating, using a current unit of the current injection device, the input current with off grid frequency into a variable input current with off grid frequency; (C) receiving, using a first reference riser and a second riser of the system, the input current with off-grid frequency from the current injection device and provide the input current with off-grid frequency to the earth grid for detecting a defective riser or a faulty connection to the earth grid when the current injection device is electrically connected to (i) the first reference riser from the plurality of the first risers at a first current injection point and (ii) the second riser at a second current injection point; (D) receiving, using a first reference riser and a pole structure of the system, the input current with off-grid frequency from the current injection device for detecting a faulty connection in a first termination point where the second riser is terminated on the pole structure when the current injection device is electrically connected to (i) the first reference riser from the plurality of the first risers at the first current injection point and (ii) the pole structure of the second equipment at a third current injection point; (E) measuring (i) a first current that is received by the second riser from the earth grid using a first current measuring device of the system, (ii) a second current that is received by the second riser from the second equipment using a second current measuring device of the system, when the first current measuring device is connected to the second riser below the second current injection point and the second current measuring device is connected to the second riser above the second current injection point; (F) measuring (i) the first current that is received by the second riser from the earth grid using the first current measuring device of the system, (ii) a third current that is received from the pole structure of the second equipment using the second current measuring device, when the first current measuring device is connected to the second riser below the first termination point and the second current measuring device is connected to the pole structure of the second equipment above the first termination point; and (G) comparing, using the system, the first current, the second current, the input current, and the third current and determining a faulty connection in (i) the first termination point, if at least one of (a) the third current that is received by the pole structure of the second equipment is below the first current that is received by the second riser from the earth grid, (b) the third current that is received by the pole structure of the second equipment, is below the input current, or (c) the third current that is received by the pole structure of the second equipment is zero, and (ii) the earth grid, if at least one of (a) the first current that is received by the second riser from the earth grid is below the second current that is received by the second riser from second equipment, (b) the first current that is received by the second riser from the earth grid is below the input current, or (c) the first current that is received by the second riser from the earth grid is zero.

In some embodiments, the method comprises (A) receiving, using the first reference riser and a frame of the second equipment of the system, the input current with off-grid frequency from the current injection device for detecting a faulty connection in a second termination point where the pole structure of the second equipment is bonded with the frame when the current injection device is electrically connected to (i) the first reference riser from the plurality of the first risers at the first current injection point and (ii) the frame of the second equipment at a fourth current injection point; (B) measuring (i) the first current that is received by the pole structure of the second equipment from the earth grid using the first current measuring device, and (ii) a fourth current that is received by the frame of the second equipment using the second current measuring device when the first current measuring device is connected to the pole structure of the second equipment below the second termination point and the second current measuring device is connected to the frame of the second equipment above the second termination point; and (C) comparing the first current, the fourth current, and the input current and determining a faulty connection in the second termination point, if at least one of (a) the fourth current that is received by the frame of the second equipment is below the first current that is received by the pole structure of the second equipment from the earth grid, (b) the fourth current that is received by the frame of the second equipment, is below the input current, or (c) the fourth current that is received by the pole structure of the second equipment is zero.

In some embodiments, the method comprises (A) receiving, using the first reference riser and the second equipment, the input current with off-grid frequency from the current injection device for detecting a faulty connection in a third termination point where the frame of the second equipment is bonded with the second equipment when the current injection device is electrically connected to (i) the first reference riser from the plurality of the first risers at the first current injection point and (ii) the second equipment at a fifth current injection point; (B) measuring (i) the first current that is received by the frame of the second equipment from the earth grid using the first current measuring device, and (ii) a fifth current that is received by the second equipment using the second current measuring device when the first current measuring device is connected to the frame of the second equipment below the third termination point and the second current measuring device is connected to the second equipment above the third termination point; and (C) comparing the first current, the fifth current, and the input current and determining a faulty connection in the third termination point, if at least one of (a) the fifth current that is received by the second equipment is below the first current that is received by the frame of the second equipment from the earth grid, (b) the fifth current that is received by the second equipment, is below the input current, or (c) the fifth current that is received by the second equipment is zero.

The system detects the faulty connection to earth in the earth grid from the equipment more accurately. The system may detect the faulty connection to earthen the earth grid from the equipment during a flow of current in the earth grid/equipment or when the earth grid/equipment is in a working condition. The system provides low input current to the earth grid/equipment, thereby avoiding the damages in the equipment/earth grid and avoid accidents while detecting the faulty connection. The low current can be provided to the earth grid/equipment even when the high current is passing through the earth grid/equipment without shutting down the high current in the earth grid. The low current with off grid frequency provided to the earth grid/equipment for detecting the faulty connection without disturbing the high current in the earth grid/equipment with a grid frequency. When the faulty connection is detected in the earth grid/equipment, an area of the faulty connection below/above ground is excavated or identified and the connection in the area is repaired.

These and other aspects of the embodiments herein will be better appreciated and understood when considered in conjunction with the following description and the accompanying drawings. It should be understood, however, that the following descriptions, while indicating preferred embodiments and numerous specific details thereof, are given by way of illustration and not of limitation. Many changes and modifications may be made within the scope of the embodiments herein, and the embodiments herein include all such modifications.

### BRIEF DESCRIPTION OF THE DRAWINGS

The embodiments herein will be better understood from the following detailed description with reference to the drawings, in which:

FIG. 1 is a system view of a system for detecting a faulty connection to earth in an earth grid from an equipment according to some embodiments herein;

FIG. 2 is a system view of the system of FIG. 1 that detects aa faulty connection in a first termination point of the equipment (i.e. a second equipment) according to some embodiments herein;

FIG. 3 is a system view of the system of FIG. 1 that detects a faulty connection in a second termination point of the equipment (i.e. a second equipment) according to some embodiments herein;

FIG. 4 is a system view the system of FIG. 1 that detects a faulty connection in a third termination point of the equipment (i.e. a second equipment) according to some embodiments herein;

FIG. 5 is a block diagram of the current injection device of FIG. 1 that provides a low input current to the earth grid or the equipment to detect a faulty connection in the earth grid or the equipment according to some embodiments herein; and

FIGS. 6A-6B are flow diagrams that illustrate a method detecting a faulty connection to earth in an earth grid from an equipment using the system of FIG. 1 according to some embodiments herein.

### DETAILED DESCRIPTION OF PREFERRED EMBODIMENTS

The embodiments herein and the various features and advantageous details thereof are explained more fully with reference to the non-limiting embodiments that are illustrated in the accompanying drawings and detailed in the following description. Descriptions of well-known components and processing techniques are omitted so as to not unnecessarily obscure the embodiments herein. The examples used herein are intended merely to facilitate an understanding of ways in which the embodiments herein may be practiced and to further enable those of skill in the art to practice the embodiments herein. Accordingly, the examples should not be construed as limiting the scope of the embodiments herein.

As mentioned, there remains a need for a system and method for detecting the faulty connections in the earth grid or the equipment using a current injection device and a current measuring device. The embodiments herein achieve this by providing a low input current to the earth grid and the equipment to detect the faulty connections to earth in the earth grid from the equipment even when the high current is flown in the earth grid. Referring now to the drawings, and more particularly to FIGS. 1 to 6B, where similar reference characters denote corresponding features consistently throughout the figures, preferred embodiments are shown.

FIG. 1 is a system view of a system for detecting a faulty connection to earth in an earth grid 104 from an equipment according to some embodiments herein. The system includes an earth grid 104, a plurality of equipment 102A-B, a current injection device 110 and a plurality of current measuring devices (116, 118). The plurality of equipment 102A-B is connected to the earth grid 104. The plurality of equipment 102A-B includes a first equipment 102A and a second equipment 102B. The first equipment 102A is connected to the earth grid 104 through a plurality of first risers 106A-B. The second equipment 102B is connected to the earth grid 104 through a second riser 108. The current injection device 110 includes a frequency converter and a current unit. The frequency converter modifies an input current with grid frequency into an input current with off grid frequency. The current unit regulates the input current with off grid frequency into a variable input current with off grid frequency. When the current injection device 110 is electrically connected to (i) a first reference riser 106A from the plurality of the first risers 106A-B at a first current injection point 112 and (ii) the second riser 108 at a second current injection point 114, the first reference riser 106A and the second riser 108 receive the input current with off-grid frequency from the current injection device 110 and provide the input current with off-grid frequency to the earth grid 104 for detecting a defective riser or a faulty to the earth grid 104. When the first current measuring device 116 is connected to the second riser 108 below the second current injection point 114 and the second current measuring device 118 is connected to the second riser 108 above the second current injection point 114, the first current measuring device 116 measures a first current that is received by the second riser 108 from the earth grid 104 and the second current measuring device 118 measures a second current that is received by the second riser 108 from the second equipment.

The system compares the first current, the second current, and the input current and determines a faulty connection in the earth grid 104, if at least one of (a) the first current that is received by the second riser 108 from the earth grid 104 is below the second current that is received by the second riser 108 from the second equipment 102B, (b) the first current that is received by the second riser 108 from the earth grid 104 is below the input current, or (c) the first current that is received by the second riser 108 from the earth grid 104 is zero.

In some embodiments, the first current injection point 112 is a point in the first reference riser 106A at which the input current is injected by the current injection device 110. In some embodiments, the second current injection point 114 is a point in the second riser 108 at which the input current is injected by the current injection device 110.

In some embodiments, the second equipment 102B includes a body of equipment such as a frame 124, a pole structure 122, or any suitable means of connecting the second equipment 102B to the earth grid 104.

In some embodiments, the input current ranges from 1 ampere to 20 amperes. In some embodiments, the input current ranges from 1 ampere to 40 amperes. In some embodiments, the input current ranges from 400 amperes. In some embodiments, the input current comprises an alternate current (AC) or a direct current (DC). In some embodiments, the first reference riser 106A is a conductor that connects the current injection device 110 and the earth grid 104.

In some embodiments, the first reference riser 106A is a node taken from the earth grid 104 to provide the input current from the current injection device 110 to the earth grid 104. The second riser 108 is a node taken from the second equipment 102B to provide the input current from the current injection device 110 to the second equipment 102B.

In some embodiments, the second riser 108 is a conductor that is connected with (i) the second equipment 102B to receive the input current from the second equipment 102B and (ii) the earth grid 104 to receive the input current from the earth grid 104. The input current from the second equipment 102B and the input current from the earth grid 104 are provided to the first current measuring device 116 and the second current measuring device 118 for measuring the first current and the second current respectively.

In some embodiments, the system may include a temporary riser that is connected to the second equipment 102B and a reference riser of a third equipment of the plurality of equipment during testing. When the current injection device 110 injects the input current to the second riser 108 on the second equipment 102B, the first current measuring device 116 that is connected to the second riser 108 measures the first current received by the second riser from the second equipment 102B and the second current measuring device 118 that is implemented on the second riser 108 measures the second current received from the second equipment 102B and the temporary riser that is connected to the second equipment 102B. The system then compares the first current and the second current that are measured and detects a faulty connection in the second equipment 102B if the first current measured is lesser than the second current or vice versa.

In some embodiment, the second equipment 102B has a first pole structure and a second pole structure. When the second equipment 102B is not accessible for testing, the system detects a faulty connection in the second equipment 102B by injecting the input current at the second injection point in the first pole structure and measuring the current received by the second pole structure using the current measuring device 110.

The plurality of equipment 106A-B is connected with the earth grid 104 to receive a current from electrical substations. In some embodiments, the current may be a grid current. In some embodiments, the earth grid 104 is buried under the earth to dissipate fault currents flowing in from above grade steel structures. In some embodiments, the current from the electrical substations flows to the plurality of equipment 106A-B through the earth grid 104. The plurality of equipment 106A-B may be any of: current transformer, potential transformer, machines, motors, and the like. In some embodiments, the plurality of equipment 106A-B connected with the earth grid 104 receives lesser current with low voltage if there is some breakage in the earth grid 104. The system detects the faulty connection in the earth grid 104 buried under the earth using the current injection device 110 and the current measuring devices (116, 118). In some embodiments, the earth grid 104 is made of at least one of copper or aluminium. The system detects the faulty connection in the earth grid 104 without disturbing or shutting down the grid current.

The current injection device 110 is connected with the earth grid 104 to provide a low input current to detect the faulty connection in the earth grid 104 buried under the earth without excavating. In some embodiments, the current injection device 110 receives the input current from an electrical grid connected with the substations. In some embodiments, the system includes a voltage regulator that is used to monitor a flow of the input current with off grid frequency and to regulate the voltage. In some embodiments, the voltage regulator includes a capacitor to regulate the voltage.

In some embodiments, the grid frequency and the off-grid frequency is different for providing the low input current to the earth grid 104 when the high grid current is flowing in the earth grid 104.

The system detects that the earth grid 104 is weakly connected with the second riser 108 or the second equipment 102B if the second current is below the first current. The system detects that the second riser 108 that is under test is weakly connected with the earth grid 104 if the first current is below the second current. The system detects that the second riser 108 that is under test is open towards the second equipment 102B or the earth grid 104 if the second current or the first current is zero. In some embodiments, the first and second currents are measured with an increased excitation voltage to determine an extent of weakness of the connection. In some embodiments, the voltage drop is also measured along with the first and second currents to accurately determine a condition of the riser that is under test.

The system detects the faulty connection to earth in the earth grid 104 from the second equipment 102B more accurately. The system may detect the faulty connection to earth in the earth grid 104 from the second equipment 102B during a flow of current in the earth grid 104/the second equipment 102B or when the earth grid 104/the second equipment 102B is in a working condition. The system provides low input current to the earth grid 104/the second equipment 102B, thereby avoiding the damages in the second equipment 102B/earth grid 104 and avoid accidents while detecting the faulty connection. The low current can be provided to the earth grid 104/the second equipment 102B even when the high current is passing through the earth grid/equipment without shutting down the high current in the earth grid 104. The low current with off grid frequency provided to the earth grid 104/the second equipment 102B for detecting the faulty connection without disturbing the high current in the earth grid 104/the second equipment 102B with a grid frequency. When the faulty connection is detected in the earth grid 104/the second equipment 102B, an area of the faulty connection below/above ground is excavated or identified and the connection in the area is repaired.

FIG. 2 is a system view of the system of FIG. 1 that detects a faulty connection in a first termination point 202 of the equipment (i.e. a second equipment 102B) according to some embodiments herein. The first reference riser 106A and the pole structure 122 receive the input current with off-grid frequency from the current injection device 110 for detecting a faulty connection in a first termination point 202 where the second riser 108 is terminated on the pole structure when the current injection device 110 is electrically connected to (i) the first reference riser 106A from the plurality of the first risers 106A-B at the first current injection point 112 and (ii) a pole structure 122 of the second equipment 102B at a third current injection point 204. The first current measuring device 116 then measures the first current that is received by the second riser 108 from the earth grid 104 and the second current measuring device 118 measures a third current that is received from the pole structure 122 of the second equipment 102B when the first current measuring device 116 is connected to the second riser 108 below the first termination point 202 and the second current measuring device 118 is connected to the pole structure 122 of the second equipment 102B above the first termination point 202. The system then compares the first current, the second current, the third current, and the input current and determines a faulty connection in the first termination point 202, if at least one of (a) the third current that is received by the pole structure 122 of the second equipment 102B is below the first current that is received by the second riser 108 from the earth grid 104, (b) the third current that is received by the pole structure 122 of the second equipment 102B, is below the input current, or (c) the third current that is received by the pole structure 122 of the second equipment 102B is zero.

In some embodiments, the third current injection point 204 is a point in the pole structure 122 of the second equipment 102B at which the input current is injected by the current injection device 110. In some embodiments, the first termination point 202 is a termination point at which the second riser 108 is terminated on the pole structure 122 of the second equipment 102B. FIG. 3 is a system view of the system of FIG. 1 that detects a faulty connection in a second termination point 302 of the equipment (i.e. a second equipment 102B) having a single riser (i.e. a second riser 108) according to some embodiments herein. The first reference riser 106A and the frame 124 of the second equipment 102B receive the input current with off-grid frequency from the current injection device 110 for detecting a faulty connection in a second termination point 302 where the pole structure 122 of the second equipment 102B is bonded with the frame 124 when the current injection device 110 is electrically connected to (i) the first reference riser 106A from the plurality of the first risers 106A-B at the first current injection point 112 and (ii) a frame 124 of the second equipment 102B at a fourth current injection point 304. The first current measuring device 116 measures the first current that is received by the pole structure 122 of the second equipment 102B from the earth grid 104 and the second current measuring device 118 measures a fourth current that is received by the frame 124 of the second equipment 102B when the first current measuring device 116 is connected to the pole structure 122 of the second equipment 102B below the second termination point 302 and the second current measuring device 118 is connected to the frame 124 of the second equipment 102B above the second termination point 302. The system then compares the first current, the fourth current, and the input current and determines a faulty connection in the second termination point 302, if at least one of (a) the fourth current that is received by the frame 124 of the second equipment 102B is below the first current that is received by the pole structure of the second equipment 102B from the earth grid 104, (b) the fourth current that is received by the frame 124 of the second equipment 102B, is below the input current, or (c) the fourth current that is received by the pole structure of the second equipment 102B is zero.

In some embodiments, the fourth current injection point 304 is a point in the frame 124 of the second equipment 102B at which the input current is injected by the current injection device 110. In some embodiments, the second termination point 302 is a termination point at which the pole structure 122 of the second equipment 102B is bonded with the frame 124 of the second equipment 102B.

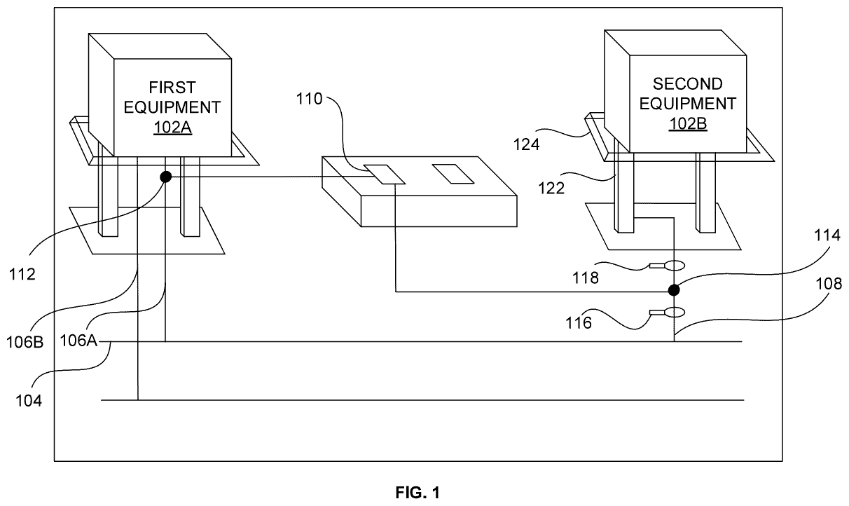

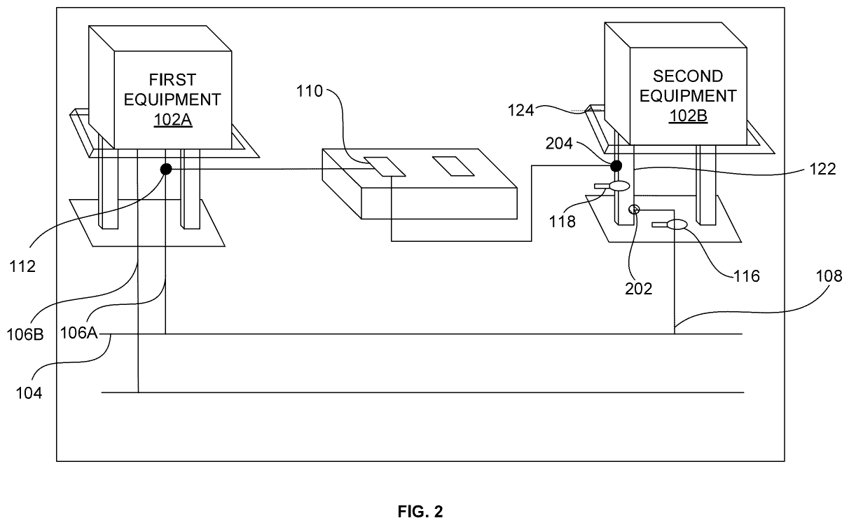

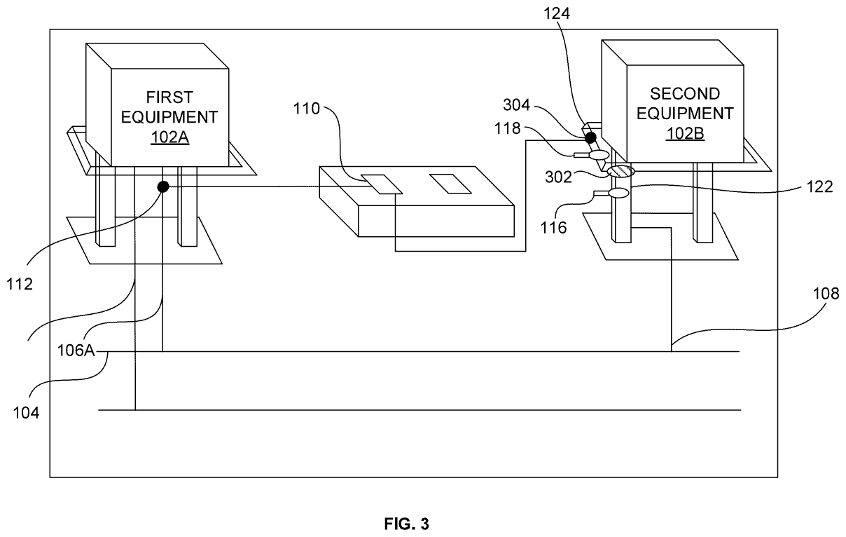

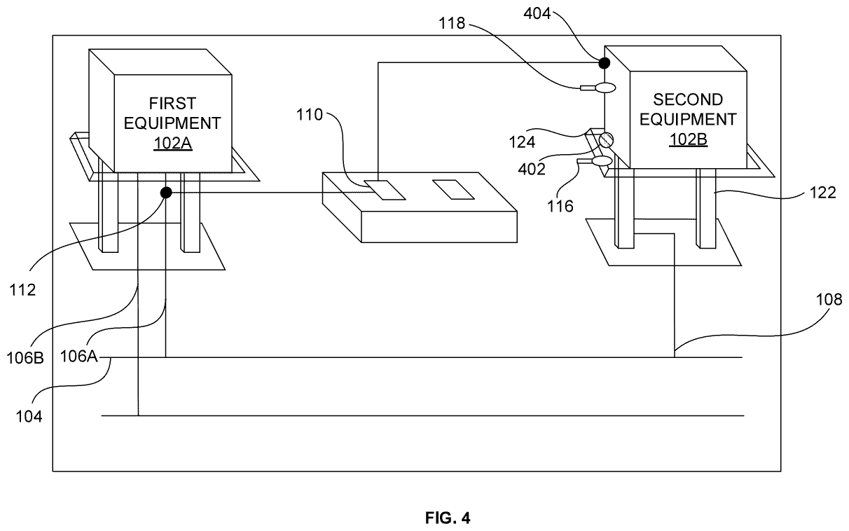

FIG. 4 is a system view of the system of FIG. 1 that detects a faulty connection in a third termination point 402 of the equipment (i.e. a second equipment 102B) according to some embodiments herein. The first reference riser 106A and the second equipment 102B receive the input current with off-grid frequency from the current injection device 110 for detecting a faulty connection in a third termination point 402 where the frame 124 of the second equipment 102B is bonded with the second equipment 102B when the current injection device 110 is electrically connected to (i) the first reference riser 106A from the plurality of the first risers 106A-B at the first current injection point 112 and (ii) the second equipment 102B at a fifth current injection point 404. The first current measuring device 116 measures the first current that is received by the frame 124 of the second equipment 102B from the earth grid 104 and the second current measuring device 118 measures a fifth current that is received by the second equipment 102B when the first current measuring device 116 is connected to the frame 124 of the second equipment 102B below the third termination point 402 and the second current measuring device 118 is connected to the second equipment 102B above the third termination point 402. The system then compares the first current, the fifth current, and the input current and determines a faulty connection in the third termination point 402, if at least one of (a) the fifth current that is received by the second equipment 102B is below the first current that is received by the frame 124 of the second equipment 102B from the earth grid 104, (b) the fifth current that is received by the second equipment 102B, is below the input current, or (c) the fifth current that is received by the second equipment 102B is zero.

In some embodiments, the third termination point 402 is a termination point at which the frame 124 of the second equipment 102B is bonded with the second equipment 102B. In some embodiments, the fifth current injection point 404 is a point in the second equipment 102B at which the input current is injected by the current injection device 110.

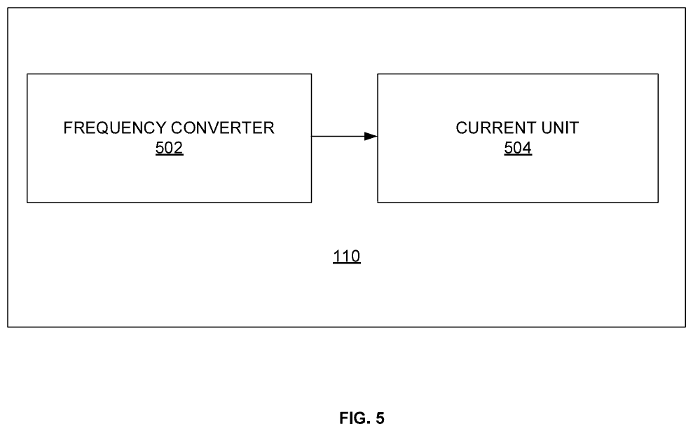

FIG. 5 is a block diagram of the current injection device 110 of FIG. 1 that provides a low input current to the earth grid 104 or the equipment (e.g. 106A-B) to detect a faulty connection in the earth grid 104 or the equipment according to some embodiments herein. The current injection device 110 includes a frequency converter 502 and a current unit 504. The frequency converter 502 receives an input current from an electrical grid connected with electrical substations. In some embodiments, the input current received from the electrical grid is in the grid frequency. The frequency converter 502 modifies the input current with grid frequency into the input current with off-grid frequency. In some embodiments, the grid frequency is modified into the off-grid frequency to provide the input current with off-grid frequency into the earth grid 104 even when the high current is flown in the earth grid 104. The output from the frequency converter 502 is provided to the current unit 504. The current unit 504 regulates the input current with off-grid frequency into the variable input current with off grid frequency. The input current may be varied between a range of 1 ampere to 20 amperes. In some embodiments, the input current with off grid frequency is regulated based on the grid current with grid frequency passing in the earth grid 104. In some embodiments, the regulated input current is provided to the earth grid 104 through a first reference riser 106A.

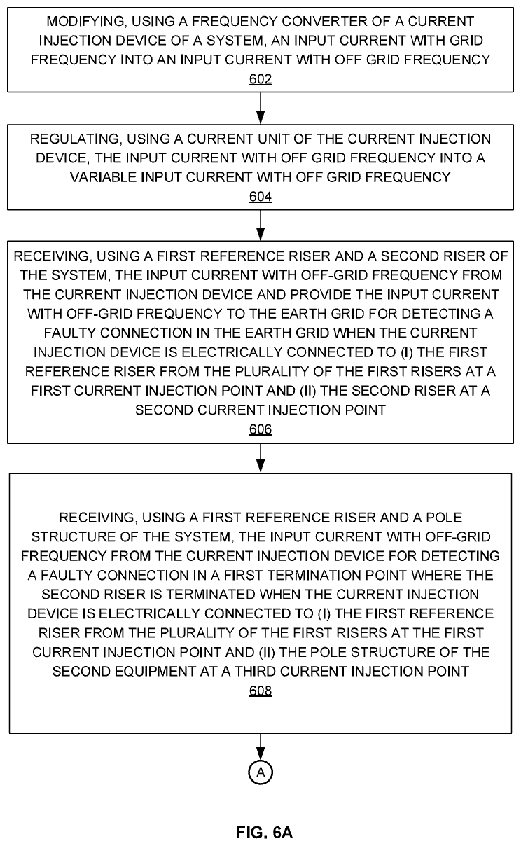

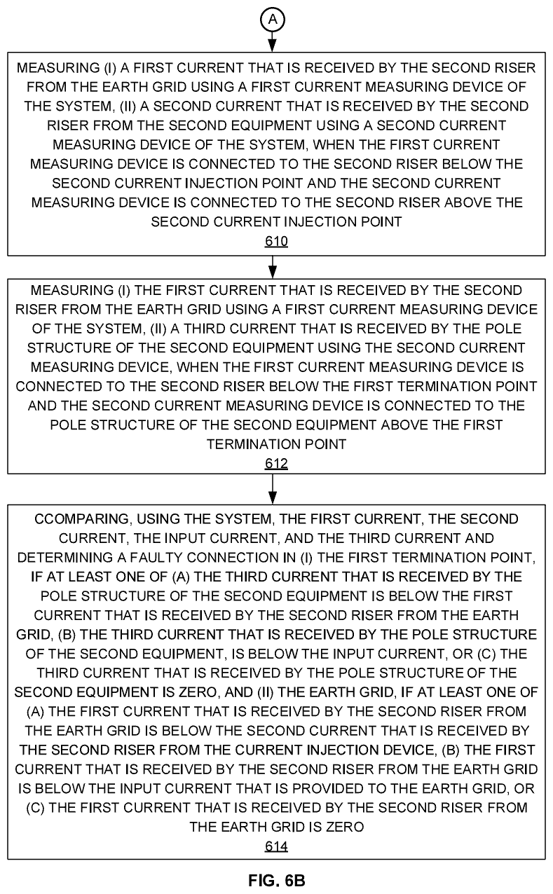

FIGS. 6A-6B are flow diagrams that illustrate a method for detecting a faulty connection to earth in the earth grid 104 from the equipment (i.e. a second equipment 102B) using the system of FIG. 1 according to some embodiments herein. The earth grid 104 is connected to a plurality of equipment 102A-B. The plurality of equipment 102A-B comprises a first equipment 102A or a second equipment 102B. The first equipment 102A is connected to the earth grid 104 through a plurality of first risers 106A-B and the second equipment 102B from the plurality of equipment 102A-Bis connected to the earth grid 104 through a second riser 108. At a step 602, an input current with grid frequency is modified, using a frequency converter 502 of a current injection device 110 of a system, into an input current with off grid frequency. At a step 604, the input current with off grid frequency is regulated, using a current unit 504 of the current injection device 110, into a variable input current with off grid frequency. At a step 606, the input current with off-grid frequency is received, using a first reference riser 106A and a second riser 108 of the system, from the current injection device 110 and the input current with off-grid frequency is provided to an earth grid 104 for detecting a defective riser or a faulty connection to the earth grid (104) when the current injection device 110 is electrically connected to (i) the first reference riser 106A from the plurality of the first risers 106A-B at a first current injection point 112 and (ii) the second riser 108 at a second current injection point 114. At a step 608, the input current with off grid frequency is received, using a first reference riser 106A and a pole structure 122 of the system, from the current injection device 110 for detecting a faulty connection in a first termination point 202 where the second riser 108 is terminated on the pole structure when the current injection device 110 is electrically connected to (i) the first reference riser 106A from the plurality of the first risers 106A-B at the first current injection point 112 and (ii) the pole structure 122 of the second equipment 102B at a third current injection point 204.

At a step 610, a first current measuring device 116 of the system measures a first current that is received by the second riser 108 from the earth grid 104 and a second current measuring device 118 of the system measures a second current that is received by the second riser 108 from the second equipment when the first current measuring device 116 is connected to the second riser 108 below the second current injection point 114 and the second current measuring device 118 is connected to the second riser 108 above the second current injection point 114. At a step 612, the first current measuring device 116 of the system measures the first current that is received by the second riser 108 from the earth grid 104 and the second current measuring device 118 measures a third current that is received from the pole structure 122 of the second equipment 102B when the first current measuring device 116 is connected to the second riser 108 below the first termination point 202 and the second current measuring device 118 is connected to the pole structure 122 of the second equipment 102B above the first termination point 202.

At a step 614, the system compares the first current, the second current, the input current, and the third current and determines a faulty connection in (i) the first termination point 202, if at least one of (a) the third current that is received by the pole structure 122 of the second equipment 102B is below the first current that is received by the second riser 108 from the earth grid 104, (b) the third current that is received by the pole structure 122 of the second equipment 102B, is below the input current, or (c) the third current that is received by the pole structure 122 of the second equipment 102B is zero, and (ii) the earth grid 104, if at least one of (a) the first current that is received by the second riser 108 from the earth grid 104 is below the second current that is received by the second riser 108 from second equipment 102B, (b) the first current that is received by the second riser 108 from the earth grid 104 is below the input current, or (c) the first current that is received by the second riser 108 from the earth grid 104 is zero.

In some embodiments, the method comprises (A) receiving, using the first reference riser 106A and a frame 124 of the second equipment 102B of the system, the input current with off-grid frequency from the current injection device 110 for detecting a faulty connection in a second termination point 302 where the pole structure 122 of the second equipment 102B is bonded with the frame 124 when the current injection device 110 is electrically connected to (i) the first reference riser 106A from the plurality of the first risers 106A-B at the first current injection point 112 and (ii) the frame 124 of the second equipment 102B at a fourth current injection point 304; (B) measuring (i) the first current that is received by the pole structure 122 of the second equipment 102B from the earth grid 104 using the first current measuring device 116, and (ii) a fourth current that is received by the frame 124 of the second equipment 102B using the second current measuring device 118 when the first current measuring device 116 is connected to the pole structure 122 of the second equipment 102B below the second termination point 302 and the second current measuring device 118 is connected to the frame 124 of the second equipment 102B above the second termination point 302; and (C) comparing the first current, the fourth current, and the input current and determining a faulty connection in the second termination point 302, if at least one of (a) the fourth current that is received by the frame 124 of the second equipment 102B is below the first current that is received by the pole structure of the second equipment 102B from the earth grid 104, (b) the fourth current that is received by the frame 124 of the second equipment 102B, is below the input current, or (c) the fourth current that is received by the pole structure of the second equipment 102B is zero.

In some embodiments, the method comprises (A) receiving, using the first reference riser 106A and the second equipment 102B, the input current with off-grid frequency from the current injection device 110 for detecting a faulty connection in a third termination point 402 where the frame 124 of the second equipment 102B is bonded with the second equipment 102B when the current injection device 110 is electrically connected to (i) the first reference riser 106A from the plurality of the first risers 106A-B at the first current injection point 112 and (ii) the second equipment 102B at a fifth current injection point 404; (B) measuring (i) the first current that is received by the frame 124 of the second equipment 102B from the earth grid 104 using the first current measuring device 116, and (ii) a fifth current that is received by the second equipment 102B using the second current measuring device 118 when the first current measuring device 116 is connected to the frame 124 of the second equipment 102B below the third termination point 402 and the second current measuring device 118 is connected to the second equipment 102B above the third termination point 402; and (C) comparing the first current, the fifth current, and the input current and determining a faulty connection in the third termination point 402, if at least one of (a) the fifth current that is received by the second equipment 102B is below the first current that is received by the frame 124 of the second equipment 102B from the earth grid 104, (b) the fifth current that is received by the second equipment 102B, is below the input current, or (c) the fifth current that is received by the second equipment 102B is zero.

The system/method detects the faulty connection to earth in the earth grid 104 from the equipment more accurately. The system/method may detect the faulty connection to earth in the earth grid 104 from the equipment during a flow of current in the earth grid 104/the equipment or when the earth grid 104/the equipment is in a working condition. The system/method provides low input current to the earth grid 104/the equipment, thereby avoiding the damages in the equipment/earth grid 104 and avoid accidents while detecting the faulty connection. The low current can be provided to the earth grid 104/the equipment even when the high current is passing through the earth grid 104/the equipment without shutting down the high current in the earth grid 104. The low current with off grid frequency provided to the earth grid 104/equipment for detecting the faulty connection without disturbing the high current in the earth grid 104/equipment with a grid frequency. When the faulty connection is detected in the earth grid 104/equipment, an area of the faulty connection below/above ground is excavated or identified and the connection in the area is repaired.

The foregoing description of the specific embodiments will so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein can be practiced with modification within the scope of the appended claims.

We claim

1. A system for detecting a faulty connection to earth in an earth grid (104) from an equipment, wherein the system comprises:
an earth grid (104);
a plurality of equipment (102A-B) that is connected to the earth grid (104), comprises:
a first equipment (102A) that is connected to the earth grid (104) through a plurality of first risers (106A-B); and
a second equipment (102B) that is connected to the earth grid (104) through a second riser (108);
a current injection device (110) comprises:
a frequency converter (502) that modifies an input current with grid frequency into an input current with off grid frequency; and
a current unit (504) that regulates the input current with off grid frequency into a variable input current with off grid frequency;
wherein when the current injection device (110) is electrically connected to (i) a first reference riser (106A) from the plurality of the first risers (106A-B) at a first current injection point (112) and (ii) the second riser (108) at a second current injection point (114), the first reference riser (106A) and the second riser (108) receive the input current with off-grid frequency from the current injection device (110) and provide the input current with off-grid frequency to the earth grid (104) for detecting a defective riser or a faulty connection to the earth grid (104),
wherein when the current injection device (110) is electrically connected to (i) the first reference riser (106A) from the plurality of the first risers (106A-B) at the first current injection point (112) and (ii) a pole structure (122) of the second equipment (102B) at a third current injection point (204), the first reference riser (106A) and the pole structure

(122) receive the input current with off-grid frequency from the current injection device (110) for detecting a faulty connection in a first termination point (202) where the second riser (108) is terminated on the pole structure; and
a plurality of current measuring devices (116, 118) comprising a first current measuring device (116) and a second current measuring device (118), wherein when the first current measuring device (116) is connected to the second riser (108) below the second current injection point (114) and the second current measuring device (118) is connected to the second riser (108) above the second current injection point (114), the first current measuring device (116) measures a first current that is received by the second riser (108) from the earth grid (104) and the second current measuring device (118) measures a second current that is received by the second riser (108) from the second equipment (102B),
wherein when the first current measuring device (116) is connected to the second riser (108) below the first termination point (202) and the second current measuring device (118) is connected to the pole structure (122) of the second equipment (102B) above the first termination point (202), the first current measuring device (116) measures the first current that is received by the second riser (108) from the earth grid (104) and the second current measuring device (118) measures a third current that is received from the pole structure (122) of the second equipment (102B),
characterized in that, wherein the system compares the first current, the second current, the third current, and the input current and determines a faulty connection in
(i) the first termination point (202), if at least one of (a) the third current that is received by the pole structure (122) of the second equipment (102B) is below the first current that is received by the second riser (108) from the earth grid (104), (b) the third current that is received by the pole structure (122) of the second equipment (102B), is below the input current, or (c) the third current that is received by the pole structure (122) of the second equipment (102B) is zero, and
(ii) the earth grid (104), if at least one of (a) the first current that is received by the second riser (108) from the earth grid (104) is below the second current that is received by the second riser (108) from the second equipment (102B), (b) the first current that is received by the second riser (108) from the earth grid (104) is below the input current, or (c) the first current that is received by the second riser (108) from the earth grid (104) is zero.

2. The system as claimed in claim 1, wherein when the current injection device (110) is electrically connected to (i) the first reference riser (106A) from the plurality of the first risers (106A-B) at the first current injection point (112) and (ii) a frame (124) of the second equipment (102B) at a fourth current injection point (304), the first reference riser (106A) and the frame (124) of the second equipment (102B) receive the input current with off-grid frequency from the current injection device (110) for detecting a faulty connection in a second termination point (302) where the pole structure (122) of the second equipment (102B) is bonded with the frame (124),
wherein when the first current measuring device (116) is connected to the pole structure (122) of the second equipment (102B) below the second termination point (302) and the second current measuring device (118) is connected to the frame (124) of the second equipment (102B) above the second termination point (302), the first current measuring device (116) measures the first current that is received by the pole structure (122) of the second equipment (102B) from the earth grid (104) and the second current measuring device (118) measures a fourth current that is received by the frame (124) of the second equipment (102B), wherein the system compares the first current, the fourth current, and the input current and determines a faulty connection in the second termination point (302), if at least one of (a) the fourth current that is received by the frame (124) of the second equipment (102B) is below the first current that is received by the pole structure of the second equipment (102B) from the earth grid (104), (b) the fourth current that is received by the frame (124) of the second equipment (102B), is below the input current, or (c) the fourth current that is received by the pole structure of the second equipment (102B) is zero.

3. The system as claimed in claim 1, wherein when the current injection device (110) is electrically connected to (i) the first reference riser (106A) from the plurality of the first risers (106A-B) at the first current injection point (112) and (ii) the second equipment (102B) at a fifth current injection point (404), the first reference riser (106A) and the second equipment (102B) receive the input current with off-grid frequency from the current injection device (110) for detecting a faulty connection in a third termination point (402) where the frame (124) of the second equipment (102B) is bonded with the second equipment (102B),
wherein when the first current measuring device (116) is connected to the frame (124) of the second equipment (102B) below the third termination point (402) and the second current measuring device (118) is connected to the second equipment (102B) above the third termination point (402), the first current measuring device (116) measures the first current that is received by the frame (124) of the second equipment (102B) from the earth grid (104) and the second current measuring device (118) measures a fifth current that is received by the second equipment (102B), wherein the system compares the first current, the fifth current, and the input current and determines a faulty connection in the third termination point (402), if at least one of (a) the fifth current that is received by the second equipment (102B) is below the first current that is received by the frame (124) of the second equipment (102B) from the earth grid (104), (b) the fifth current that is received by the second equipment (102B), is below the input current, or (c) the fifth current that is received by the second equipment (102B) is zero.

4. The system as claimed in claim 1, wherein the input current ranges from 1 ampere to 20 amperes, wherein the input current comprises an alternate current (AC) or a direct current (DC).

5. The system as claimed in claim 1, wherein the first reference riser (106A) is a conductor that connects the current injection device (110) and the earth grid (104).

6. The system as claimed in claim 1, wherein the first reference riser (106A) is a node taken from the earth grid (104) to provide the input current from the current injection device (110) to the earth grid (104), wherein the second riser (108) is a node taken from the second equipment (102B) or a body of the second equipment (102B) to provide the input current from the current injection device (110) to the second equipment (102B) or a body of the second equipment (102B).

7. The system as claimed in claim 1, wherein the second riser (108) under test is a conductor that is connected with (i) the second equipment (102B) or a body of the second equipment (102B) and (ii) the earth grid (104).

8. A method for detecting a faulty connection to earth in an earth grid (104) from an equipment, wherein the earth grid (104) is connected to a plurality of equipment (102A-B), wherein a first equipment (102A) from the plurality of equipment (102A-B) is connected to the earth grid (104) through a plurality of first risers (106A-B) and a second equipment (102B) from the plurality of equipment (102A-B) is connected to the earth grid (104) through a second riser (108), wherein the method comprises:
modifying, using a frequency converter (502) of a current injection device (110) of a system, an input current with grid frequency into an input current with off grid frequency;
regulating, using a current unit (504) of the current injection device (110), the input current with off grid frequency into a variable input current with off grid frequency;
receiving, using a first reference riser (106A) and a second riser (108) of the system, the input current with off-grid frequency from the current injection device (110) and provide the input current with off-grid frequency to the earth grid (104) for detecting a defective riser or a faulty connection to the earth grid (104) when the current injection device (110) is electrically connected to (i) the first reference riser (106A) from the plurality of the first risers (106A-B) at a first current injection point (112) and (ii) the second riser (108) at a second current injection point (114);
receiving, using a first reference riser (106A) and a pole structure (122)of the system, the input current with off-grid frequency from the current injection device (110) for detecting a faulty connection in a first termination point (202) where the second riser (108) is terminated on the pole structure when the current injection device (110) is electrically connected to (i) the first reference riser (106A) from the plurality of the first risers (106A-B) at the first current injection point (112) and (ii) the pole structure (122) of the second equipment (102B) at a third current injection point (204);
measuring (i) a first current that is received by the second riser (108) from the earth grid (104) using a first current measuring device (116) of the system, (ii) a second current that is received by the second riser (108) from the second equipment (102B) using a second current measuring device (118) of the system, when the first current measuring device (116) is connected to the second riser (108) below the second current injection point (114) and the second current measuring device (118) is connected to the second riser (108) above the second current injection point (114);
measuring (i) the first current that is received by the second riser (108) from the earth grid (104) using the first current measuring device (116) of the system, (ii) a third current that is received from the pole structure (122) of the second equipment (102B) using the second current measuring device (118), when the first current measuring device (116) is connected to the second riser (108) below the first termination point (202) and the second current measuring device (118) is connected to the pole structure (122) of the second equipment (102B) above the first termination point (202); and
characterized in that, comparing, using the system, the first current, the second current, the input current, and the third current and determining a faulty connection in
(i) the first termination point (202), if at least one of (a) the third current that is received by the pole structure (122) of the second equipment (102B) is below the first current that is received by the second riser (108) from the earth grid (104), (b) the third current that is received by the pole structure (122) of the second equipment (102B), is below the input current, or (c) the third current that is received by the pole structure (122) of the second equipment (102B) is zero, and
(ii) the earth grid (104), if at least one of (a) the first current that is received by the second riser (108) from the earth grid (104) is below the second current that is received by the second riser (108) from second equipment (102B), (b) the first current that is received by the second riser (108) from the earth grid (104) is below the input current, or (c) the first current that is received by the second riser (108) from the earth grid (104) is zero.

9. The method as claimed in claim 8, wherein the method comprises
receiving, using the first reference riser (106A) and a frame (124) of the second equipment (102B) of the system, the input current with off-grid frequency from the current injection device (110) for detecting a faulty connection in a second termination point (302) where the pole structure (122) of the second equipment (102B) is bonded with the frame (124) when the current injection device (110) is electrically connected to (i) the first reference riser (106A) from the plurality of the first risers (106A-B) at the first current injection point (112) and (ii) the frame (124) of the second equipment (102B) at a fourth current injection point (304);
measuring (i) the first current that is received by the pole structure (122) of the second equipment (102B) from the earth grid (104) using the first current measuring device (116), and (ii) a fourth current that is received by the frame (124) of the second equipment (102B) using the second current measuring device (118) when the first current measuring device (116) is connected to the pole structure (122) of the second equipment (102B) below the second termination point (302) and the second current measuring device (118) is connected to the frame (124) of the second equipment (102B) above the second termination point (302); and
comparing the first current, the fourth current, and the input current and determining a faulty connection in the second termination point (302), if at least one of (a) the fourth current that is received by the frame (124) of the second equipment (102B) is below the first current that is received by the pole structure of the second equipment (102B) from the earth grid (104), (b) the fourth current that is received by the frame (124) of the second equipment (102B), is below the input current, or (c) the fourth current that is received by the pole structure of the second equipment (102B) is zero.

10. The method as claimed in claim 8, wherein the method comprises
receiving, using the first reference riser (106A) and the second equipment (102B), the input current with off-grid frequency from the current injection device (110) for detecting a faulty connection in a third termination point (402) where the frame (124) of the second equipment (102B) is bonded with the second equipment (102B) when the current injection device (110) is electrically connected to (i) the first reference riser (106A) from the plurality of the first risers (106A-B) at the first current injection point (112) and (ii) the second equipment (102B) at a fifth current injection point (404);
measuring (i) the first current that is received by the frame (124) of the second equipment (102B) from the earth grid (104) using the first current measuring device (116), and (ii) a fifth current that is received by the second equipment (102B) using the second current measuring device (118) when the first current measuring device (116) is connected to the frame (124) of the second equipment (102B) below the third termination point (402) and the second current measuring device (118) is connected to the second equipment (102B) above the third termination point (402); and
comparing the first current, the fifth current, and the input current and determining a faulty connection in the third termination point (402), if at least one of (a) the fifth current that is received by the second equipment (102B) is below the first current that is received by the frame (124) of the second equipment (102B) from the earth grid (104), (b) the fifth current that is received by the second equipment (102B), is below the input current, or (c) the fifth current that is received by the second equipment (102B) is zero.
